(19) United States
(12) Patent Application Publication
(10) Pub. No.: US 2022/0081763 A1
(43) Pub. Date: Mar. 17, 2022

(54) ALUMINUM OXIDE PROTECTIVE COATINGS ON TURBOCHARGER COMPONENTS AND OTHER ROTARY EQUIPMENT COMPONENTS

(71) Applicant: Applied Materials, Inc., Santa Clara, CA (US)

(72) Inventors: Nitin DEEPAK, Mumbai (IN); Sarin Sundar JAINNAGAR KUPPUSWAMY, Hyderabad, Andhra Pradesh (IN); Sankalp PATIL, Bangalore (IN); Sukti CHATTERJEE, San Jose, CA (US); David Masayuki ISHIKAWA, Mountain View, CA (US); Prerna Sonthalia GORADIA, Mumbai (IN); David Alexander BRITZ, Los Gatos, CA (US); Lance A. SCUDDER, Sunnyvale, CA (US)

(21) Appl. No.: 17/477,430

(22) Filed: Sep. 16, 2021

(30) Foreign Application Priority Data
Sep. 17, 2020 (IN) 202041040353

(51) Int. Cl. C23C 16/40; C23C 14/08; C23C 16/455; F02C 6/12

(52) U.S. Cl. CPC C23C 16/403; C23C 14/081; C23C 16/45527; F05D 2300/173; F02C 6/12; F05D 2230/31; C23C 16/45553

(57) ABSTRACT

Embodiments of the present disclosure generally relate to protective coatings on turbocharger components, such as turbine wheels and compressor wheels, and other rotary equipment components and methods for depositing the protective coatings on such components. In one or more embodiments, a coated turbocharger component is provided and includes a metallic substrate containing a nickel-based alloy or superalloy, a cobalt-based alloy or superalloy, a stainless steel, or a titanium-aluminum alloy and a protective coating disposed on the metallic substrate. The protective coating contains an aluminum oxide having a purity of greater than 99 atomic percent (at %). In some examples, the metallic substrate is a turbine wheel, a compressor wheel, an impeller, a fan blade, a disk, a heat shield, a pulley, or a shaft.

### CROSS-REFERENCE TO RELATED APPLICATIONS

This application claims benefit to Indian Prov. Appl. No. 202041040353, filed Sep. 17, 2020, which is herein incorporated by reference.

### BACKGROUND

### Field

Embodiments of the present disclosure generally relate to deposition processes, and in particular to vapor deposition processes for depositing films on turbocharger components and other types of rotary equipment components.

### Description of the Related Art

Turbochargers, superchargers, and other rotary equipment typically have components which oxidize, corrode, or otherwise degrade over time due to being exposed to oxygen and high temperatures (e.g., about 500° C. to about 1,300° C.), and/or various corrosive agents. The oxidation and/or corrosion of the metallic component (e.g., turbine wheel, compressor wheel, etc.) reduces the lifetime of the overall piece of rotary device. Mechanical damage can occur which may trigger the destruction of metallic component or the collapse of the rotary device. The likelihood of such mechanical failure increases due to the continuous thermal cycling and stresses placed on the metallic component.

Therefore, there is a need for protective coatings on turbocharger components, such as turbine wheels and compressor wheels, and other rotary equipment components, and methods for depositing the protective coatings.

### SUMMARY

Embodiments of the present disclosure generally relate to protective coatings on turbocharger components, such as turbine wheels and compressor wheels, and other rotary equipment components and methods for depositing the protective coatings on such components.

In one or more embodiments, a coated turbocharger component is provided and includes a metallic substrate containing a nickel-based alloy or superalloy, a cobalt-based alloy or superalloy, a stainless steel, or a titanium-aluminum alloy and a protective coating disposed on the metallic substrate. The protective coating contains an aluminum oxide having a purity of greater than 99 atomic percent (at %). In some examples, the metallic substrate is a turbine wheel, a compressor wheel, an impeller, a fan blade, a disk, a heat shield, a pulley, or a shaft.

In other embodiments, a coated turbocharger component is provided and includes a metallic substrate, such as a turbine wheel or a compressor wheel, and a protective coating disposed on the metallic substrate. The protective coating contains an aluminum oxide having a purity of greater than 99.9 at %, the aluminum oxide contains less than 0.1 at % of an impurity, and the impurity contains sulfur, carbon, nitrogen, nickel, cobalt, tantalum, or any combination thereof.

In some embodiments, a method for producing, forming, or otherwise depositing the protective coating on a coated turbocharger component is provided and includes positioning a metallic substrate and depositing a protective coating on the metallic substrate. The protective coating contains an aluminum oxide having a purity of greater than 99 at %. In some examples, the protective coating is deposited by an atomic layer deposition (ALD) process, a plasma-enhanced ALD (PE-ALD) process, a thermal chemical vapor deposition (CVD) process, a plasma-enhanced CVD (PE-CVD) process, a pulsed-CVD process, a physical vapor deposition (PVD) process, or any combination thereof.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A depicts a coated turbocharger component, such as a turbine wheel containing a protective coating, according to one or more embodiments described and discussed herein.

FIG. 1B depicts a cross-sectional view of a portion of the coated turbocharger component illustrated in FIG. 1A, according to one or more embodiments described and discussed herein.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

Embodiments of the present disclosure generally relate to protective coatings on turbocharger components, such as turbine wheels and compressor wheels, and other rotary equipment components and methods for depositing the protective coatings on such components. The protective coatings reduce or eliminate oxidation of the component during use. The protective coatings do not or minimally affect weight, dimensional tolerances, low cycle fatigue life, and/or thermal conductivity of the component.

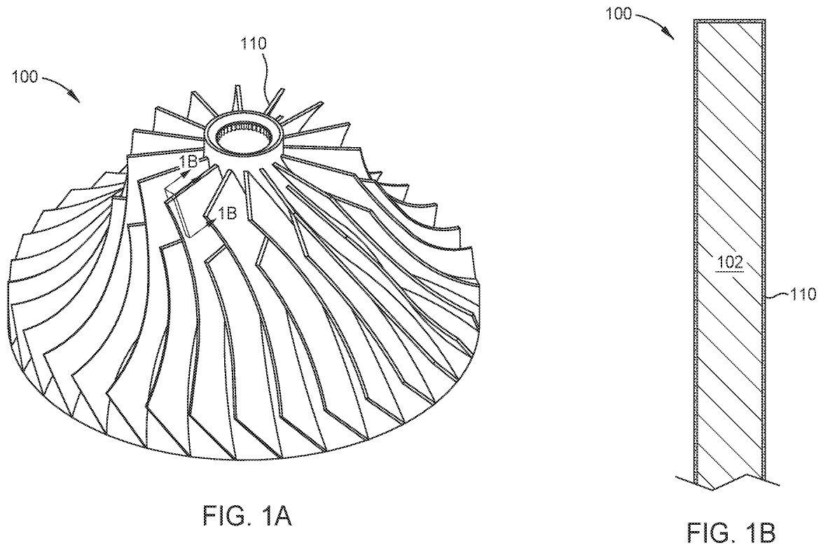

FIG. 1A depicts a coated turbocharger component 100 and FIG. 1B depicts a cross-sectional view of a portion of the coated turbocharger component 100, according to one or more embodiments described and discussed herein. The coated turbocharger component 100 contains a substrate or turbocharger component 102 containing a protective coating 110. The turbocharger component 102 can be or include a turbine wheel, a compressor wheel, or any other rotary equipment component. The protective coating 110 can be any one or more protective coatings described and discussed herein. In one or more examples, the protective coating 110 can be or include aluminum oxide.

In one or more embodiments, a coated turbocharger component or other coated component is provided and includes a metallic substrate (e.g., the underlying component) and a protective coating disposed on the metallic substrate. The metallic substrate may refer to the one or more turbocharger components, one or more other type of rotary equipment components, and/or other components. Exemplary rotary equipment components as described and discussed herein can be or include one or more components, parts, or portions thereof of a turbine, an aerospace vehicle (e.g., an aircraft or a spacecraft), a ground vehicle (e.g., automobile, truck, equipment, or train), a water vehicle (e.g., ship, boat, or other vessel), a windmill, a ground-based power generation system, or other devices that can include one or more turbines (e.g., generators, compressors (centrifugal compressor), pumps, turbo fans, super chargers, and the like). Exemplary rotary equipment components and metallic substrates can be or include a turbine wheel (e.g., exducer), a compressor wheel (e.g., inducer), an impeller, a fan blade, a disk, a turbine blade, a turbine blade root (e.g., fir tree or dovetail), a turbine disk, a turbine vane, a support member, a frame, a rib, a fin, a pin fin, a fuel nozzle, a combustor liner, a heat shield, a combustor shield, a heat exchanger, a fuel line, a valve, an internal cooling channel, a pulley, a shaft, any combination thereof, or other components, parts, or portions of a turbocharger, rotary equipment, or any other aerospace component or part that can benefit from the protective coatings described and discussed herein. The rotary equipment component and metallic substrate typically has a thickness of about 1 mm, about 1.5 mm, or about 2 mm to about 3 mm, about 5 mm, about 8 mm, or about 10 mm. For example, the rotary equipment component and metallic substrate can have a thickness of about 1 mm to about 5 mm or about 2 mm to about 3 mm.

The rotary equipment component and/or the metallic substrate can be made of, contain, or otherwise include one or more metals, such as one or more stainless steels (e.g., one or more austenitic stainless steels), one or more nickel-based alloys or superalloys (e.g., greater than 50 at % of nickel), one or more Inconel alloys (e.g. Inconel 713 (IN713) alloy, Inconel 713C (IN713C) alloy, or Inconel 713LC (IN713LC) alloy), one or more titanium-aluminum alloys, MAR-M247 alloy, RCV11 nickel-based alloy, RCV09 nickel-based alloy, one or more Hastelloy alloys, one or more Cannon-Muskegon alloys, one or more PWA alloys, one or more Rene alloys (e.g., Rene 41 alloy), one or more Invar alloys (e.g., e.g., iron and nickel alloy), one or more Invoco alloys (e.g., iron nickel cobalt alloys), one or more cobalt-based alloys or superalloys (e.g., greater than 50 at % of cobalt), nickel, chromium, cobalt, chromium-cobalt alloys, molybdenum, iron, steel, titanium, any alloy thereof, or any combination thereof.

The protective coating reduces or eliminates oxidation, corrosion, and/or mechanical damage of the rotary equipment component during use. In one or more embodiments, the protective coating contains aluminum oxide having a high purity, such as greater than 95 atomic percent (at %), such as about 96 at %, about 97 at %, about 98 at %, or about 99 at %. In one or more examples, the protective coating contains aluminum oxide having a purity of greater than 99 at %, such as about or greater than 99.5 at %, about or greater than 99.9 at %, about or greater than 99.95 at %, about or greater than 99.99 at %, about or greater than 99.995 at %, about or greater than 99.999 at %, or about or greater than 99.9999 at %. For example, the protective coating contains aluminum oxide having a purity of greater than 99 at % to about or greater than 99.9999 at %, greater than 99 at % to about or greater than 99.999 at %, greater than 99 at % to about or greater than 99.99 at %, or greater than 99 at % to about or greater than 99.9 at %.

Additives, such as various desired elements, contained in the aluminum oxide of the protective coating provide enhanced properties for the stability of the overall protective coating and reduce or eliminate oxidation of the underlying metallic substrate. In one or more embodiments, the aluminum oxide of the protective coating contains one or more desired elements which can be or include hafnium, titanium, chromium, yttrium, zirconium, niobium, platinum, palladium, silicon, rhodium, ytterbium, strontium, barium, lanthanide, cerium, neodymium, samarium, gadolinium, terbium, dysprosium, holmium, erbium, thulium, lutetium, oxides thereof, and any combination thereof. The concentration of the desired elements can be about 1 ppm, about 10 ppm, about 20 ppm, about 50 ppm, about 0.0001 at %, about 0.0005 at %, or about 0.001 at % to about 0.005 at %, about 0.01 at %, about 0.05 at %, about 0.1 at %, or about 0.5 at %. For example, the concentration of the desired elements can be about 1 ppm to about 0.5 at %, about 1 ppm to about 0.01 at %, about 1 ppm to about 0.001 at %, or about 1 ppm to about 0.0001 at %.

Impurities, such as various undesired elements, contained in the aluminum oxide of the protective coating reduce the stability of the overall coating and may cause the protective coating to peel or otherwise fail. As such, the underlying metallic substrate, if exposed, can be susceptible to oxidation and/or corrosion. In one or more embodiments, the aluminum oxide of the protective coating contains one or more undesired elements which can be or include sulfur, carbon, nitrogen, nickel, cobalt, tantalum, or any combination thereof. The concentration of the impurity of undesired element in the aluminum oxide is less than 0.1 at %, such as about or less than 0.01 at %, about or less than 0.005 at %, about or less than 0.001 at %, about or less than 0.0005 at %, about or less than 0.0001 at % to about 80 ppm, about 50 ppm, about 35 ppm, about 20 ppm, about 10 ppm, about 5 ppm, or about 1 ppm.

In one or more embodiments, the coated turbocharger component includes a metallic substrate, such as a turbine wheel or a compressor wheel, and the protective coating is disposed on the metallic substrate, where the protective coating contains an aluminum oxide having a purity of greater than 99.9 at %, the aluminum oxide contains less than 0.1 at % of an impurity, and the impurity contains sulfur, carbon, nitrogen, nickel, cobalt, tantalum, or any combination thereof.

The protective coating has a thickness of about 10 nm, about 50 nm, about 80 nm, about 100 nm, about 150 nm, about 200 nm, about 250 nm, about 300 nm, or about 400 nm to about 500 nm, about 700 nm, about 850 nm, about 1,000 nm, about 1,200 nm, about 1,350 nm, about 1,500 nm, about 1,800 nm, about 2,000 nm, about 2,500 nm, about 3,000 nm, or thicker. For example, the protective coating has a thickness of about 10 nm to about 3,000 nm, about 10 nm to about 2,000 nm, about 10 nm to about 1,500 nm, about 10 nm to about 1,200 nm, about 10 nm to about 1,000 nm, about 10 nm to about 850 nm, about 10 nm to about 700 nm, about 10 nm to about 500 nm, about 10 nm to about 300 nm, about 10 nm to about 200 nm, about 10 nm to about 100 nm, about 10 nm to about 50 nm, about 100 nm to about 2,000 nm, about 100 nm to about 1,500 nm, about 100 nm to about 1,200 nm, about 100 nm to about 1,000 nm, about 100 nm to about 850 nm, about 100 nm to about 700 nm, about 100 nm to about 500 nm, about 100 nm to about 300 nm, about 100 nm to about 200 nm, about 200 nm to about 2,000 nm, about 200 nm to about 1,500 nm, about 200 nm to about 1,200 nm, about 200 nm to about 1,000 nm, about 200 nm to about 850 nm, about 200 nm to about 700 nm, about 200 nm to about 500 nm, about 200 nm to about 300 nm, about 300 nm to about 2,000 nm, about 300 nm to about 1,500 nm, about 300 nm to about 1,200 nm, about 300 nm to about 1,000 nm, about 300 nm to about 850 nm, about 300 nm to about 700 nm, or about 300 nm to about 500 nm.

The protective coating can be deposited, formed, disposed, or otherwise produced on any surface of the rotary equipment component or the metallic substrate including one or more outer or exterior surfaces and/or one or more inner or interior surfaces. In one or more embodiments, the rotary equipment component or the metallic substrate is completely coated with or encapsulated by the protective coating. The protective coating has an average surface roughness (Ra) of about 1 μm to about 100 μm. The protective coating provides protection from oxidation and/or corrosion when the rotary equipment components are exposed to air, oxygen, sulfur and/or sulfur compounds, acids, bases, salts (e.g., Na, K, Mg, Li, or Ca salts), or any combination thereof. The rotary equipment components may be exposed to these conditions during normal operation or during a cleaning process to remove any carbon buildup.

In one or more embodiments, the protective coating can have a relatively high degree of uniformity. The protective coating can have a uniformity of less than 50%, less than 40%, or less than 30% of the thickness of the respective protective coating. The protective coating can have a uniformity from about 0%, about 0.5%, about 1%, about 2%, about 3%, about 5%, about 8%, or about 10% to about 12%, about 15%, about 18%, about 20%, about 22%, about 25%, about 28%, about 30%, about 35%, about 40%, about 45%, or less than 50% of the thickness. For example, the protective coating can have a uniformity from about 0% to about 50%, about 0% to about 40%, about 0% to about 30%, about 0% to less than 30%, about 0% to about 28%, about 0% to about 25%, about 0% to about 20%, about 0% to about 15%, about 0% to about 10%, about 0% to about 8%, about 0% to about 5%, about 0% to about 3%, about 0% to about 2%, about 0% to about 1%, about 1% to about 50%, about 1% to about 40%, about 1% to about 30%, about 1% to less than 30%, about 1% to about 28%, about 1% to about 25%, about 1% to about 20%, about 1% to about 15%, about 1% to about 10%, about 1% to about 8%, about 1% to about 5%, about 1% to about 3%, about 1% to about 2%, about 5% to about 50%, about 5% to about 40%, about 5% to about 30%, about 5% to less than 30%, about 5% to about 28%, about 5% to about 25%, about 5% to about 20%, about 5% to about 15%, about 5% to about 10%, about 5% to about 8%, about 10% to about 50%, about 10% to about 40%, about 10% to about 30%, about 10% to less than 30%, about 10% to about 28%, about 10% to about 25%, about 10% to about 20%, about 10% to about 15%, or about 10% to about 12% of the thickness. In some examples, the protective coating has a thickness variation of less than 20%, less than 10%, less than 5%.

### Clean Process

Prior to producing or otherwise depositing the protective coating, the rotary equipment component can optionally be exposed to one or more cleaning processes. One or more contaminants are removed from the rotary equipment component to produce the cleaned surface during the cleaning process. The contaminant can be or include oxides, organics or organic residues, carbon, oil, soil, particulates, debris, and/or other contaminants, or any combination thereof. These contaminants are removed prior to producing the protective coating on the rotary equipment component.

The cleaning process can be or include one or more basting or texturing processes, vacuum purges, solvent clean, acid clean, basic or caustic clean, wet clean, ozone clean, plasma clean, sonication, or any combination thereof. Once cleaned and/or textured, the subsequently deposited protective coating has stronger adhesion to the cleaned surfaces or otherwise altered surfaces of the rotary equipment component than if otherwise not exposed to the cleaning process.

In one or more examples, the surfaces of the rotary equipment component can be blasted with or otherwise exposed to beads, sand, carbonate, or other particulates to remove oxides and other contaminates therefrom and/or to provide texturing to the surfaces of the rotary equipment component. In some examples, the rotary equipment component can be placed into a chamber within a pulsed push-pull system and exposed to cycles of purge gas or liquid (e.g., N₂, Ar, He, one or more alcohols (methanol, ethanol, propanol, butanol, and/or larger alcohols), H₂O, or any combination thereof) and vacuum purges to remove debris from small holes on the rotary equipment component. In other examples, the surfaces of the rotary equipment component can be exposed to hydrogen plasma, oxygen or ozone plasma, and/or nitrogen plasma, which can be generated in a plasma chamber or by a remote plasma system.

In some examples, such as for organic removal or oxide removal, the surfaces of the rotary equipment component can be exposed to a hydrogen plasma, then degassed, then exposed to ozone treatment. In other examples, such as for organic removal, the surfaces of the rotary equipment component can be exposed to a wet clean that includes: soaking in an alkaline degreasing solution, rinsing, exposing the surfaces to an acid clean (e.g., sulfuric acid, phosphoric acid, hydrochloric acid, hydrofluoric acid, or any combination thereof), rinsing, and exposing the surfaces deionized water sonication bath. In some examples, such as for oxide removal, the surfaces of the rotary equipment component can be exposed to a wet clean that includes: exposing the surfaces to a dilute acid solution (e.g., acetic acid hydrochloric acid, hydrofluoric acid, or combinations thereof), rinsing, and exposing the surfaces deionized water sonication bath. In one or more examples, such as for particle removal, the surfaces of the rotary equipment component can be exposed to sonication (e.g., megasonication) and/or a supercritical fluid (carbon dioxide, water, one or more alcohols) wash, followed by exposing to cycles of purge gas or liquid (e.g., N₂, Ar, He, one or more alcohols, H₂O, or any combination thereof) and vacuum purges to remove particles from and dry the surfaces. In some examples, the rotary equipment component can be exposed to heating or drying processes, such as heating the rotary equipment component to a temperature of about 50° C., about 65° C., or about 80° C. to about 100° C., about 120° C., or about 150° C. and exposing to surfaces to the purge gas. The rotary equipment component can be heated in an oven or exposed to lamps for the heating or drying processes. Optionally, hot gas can be forced through internal passages to accelerate drying. Optionally, the component can be dried in reduced atmosphere without heating or with heating.

In various embodiments, the cleaned surface of the rotary equipment component can be one or more interior surfaces and/or one or more exterior surfaces of the rotary equipment component. The cleaned surface of the rotary equipment component can be or include one or more material, such as nickel-based alloys or superalloys, cobalt-based alloys or superalloys, stainless steel, nickel, cobalt, chromium, molybdenum, iron, titanium, alloys thereof, or any combination thereof.

### Vapor Deposition Process

In one or more embodiments, the protective coating can be deposited, disposed, formed, or otherwise produced on the metallic substrate to produce on the coated turbocharger component. The protective coating reduces or suppresses oxidation, low cycle fatigue life and/or stress corrosion cracking of the turbine wheels, the compressor wheels, and other rotary equipment components. The metallic substrate is positioned and then the protective coating is deposited on the metallic substrate by one or more vapor deposition processes. In some examples, the protective coating is deposited, formed, disposed, or otherwise produced by an atomic layer deposition (ALD) process, a plasma-enhanced ALD (PE-ALD) process, a thermal chemical vapor deposition (CVD) process, a plasma-enhanced CVD (PE-CVD) process, a pulsed-CVD process, a physical vapor deposition (PVD) process, or any combination thereof.

In one or more embodiments, a method for depositing a protective coating on the rotary equipment component or metallic substrate includes sequentially exposing the rotary equipment component or metallic substrate to an aluminum precursor and one or more oxidizing agents to form an aluminum oxide on a surface the rotary equipment component or metallic substrate by an ALD process.

The aluminum precursor can be or include one or more of aluminum alkyl compounds, one or more of aluminum alkoxy compounds, one or more of aluminum acetylacetonate compounds, substitutes thereof, complexes thereof, abducts thereof, salts thereof, or any combination thereof. Exemplary aluminum precursors can be or include trimethylaluminum, triethylaluminum, tripropylaluminum, tributylaluminum, trimethoxyaluminum, triethoxyaluminum, tripropoxyaluminum, tributoxyaluminum, aluminum acetylacetonate (Al(acac)₃, also known as, tris(2,4-pentanediono) aluminum), aluminum hexafluoroacetylacetonate (Al(hfac)₃), trisdipivaloylmethanatoaluminum (DPM₃Al; (C₁₁H₁₉O₂)₃Al), isomers thereof, complexes thereof, abducts thereof, salts thereof, or any combination thereof.

In one or more examples, the precursor is or contains one or more aluminum alkyl compounds, such as trimethyl aluminum (TMA). The aluminum alkyl compound (e.g., TMA) has a purity of greater than 95%, greater than 97%, or greater than 99%, such as about 99.3%, about 99.5 wt %, about 99.7 wt %, or about 99.9 wt % to about 99.95 wt %, about 99.99 wt %, about 99.995 wt %, about 99.999 wt %, about 99.9999 wt %, or greater. In one or more examples, the aluminum alkyl compound (e.g., TMA) has a purity of 99.5 wt % or greater, such as about 99.9 wt % to about 99.999 wt %. Exemplary oxidizing agents can be or include water (e.g., steam), oxygen (O₂), atomic oxygen, ozone, nitrous oxide, one or more peroxides (e.g., hydrogen peroxide, other inorganic peroxides, organic peroxides), one or more alcohols (e.g., methanol, ethanol, propanol, or higher alcohols), plasmas thereof, or any combination thereof.

In one or more embodiments, the vapor deposition process is an ALD process and the method includes sequentially exposing the surface of the rotary equipment component (e.g., turbocharger component or metallic substrate) to the aluminum precursor and the oxidizing agent to form the deposited layer of aluminum oxide. Each cycle of the ALD process includes exposing the surface of the rotary equipment component to the aluminum precursor, conducting a pump-purge, exposing the rotary equipment component to the oxidizing agent, and conducting a pump-purge to form the deposited layer of aluminum oxide. The order of the aluminum precursor and the oxidizing agent can be reversed, such that the ALD cycle includes exposing the surface of the rotary equipment component to the oxidizing agent, conducting a pump-purge, exposing the rotary equipment component to the aluminum precursor, and conducting a pump-purge to form the deposited layer of aluminum oxide.

In some examples, during each ALD cycle, the rotary equipment component is exposed to the aluminum precursor for about 0.1 seconds to about 10 seconds, the oxidizing agent for about 0.1 seconds to about 10 seconds, and the pump-purge for about 0.5 seconds to about 30 seconds. In other examples, during each ALD cycle, the rotary equipment component is exposed to the aluminum precursor for about 0.5 seconds to about 3 seconds, the oxidizing agent for about 0.5 seconds to about 3 seconds, and the pump-purge for about 1 second to about 10 seconds.

Each ALD cycle is repeated from 2, 3, 4, 5, 6, 8, about 10, about 12, or about 15 times to about 18, about 20, about 25, about 30, about 40, about 50, about 65, about 80, about 100, about 120, about 150, about 200, about 250, about 300, about 350, about 400, about 500, about 800, about 1,000, or more times to form the deposited layer of aluminum oxide. For example, each ALD cycle is repeated from 2 times to about 1,000 times, 2 times to about 800 times, 2 times to about 500 times, 2 times to about 300 times, 2 times to about 250 times, 2 times to about 200 times, 2 times to about 150 times, 2 times to about 120 times, 2 times to about 100 times, 2 times to about 80 times, 2 times to about 50 times, 2 times to about 30 times, 2 times to about 20 times, 2 times to about 15 times, 2 times to about 10 times, 2 times to 5 times, about 8 times to about 1,000 times, about 8 times to about 800 times, about 8 times to about 500 times, about 8 times to about 300 times, about 8 times to about 250 times, about 8 times to about 200 times, about 8 times to about 150 times, about 8 times to about 120 times, about 8 times to about 100 times, about 8 times to about 80 times, about 8 times to about 50 times, about 8 times to about 30 times, about 8 times to about 20 times, about 8 times to about 15 times, about 8 times to about 10 times, about 20 times to about 1,000 times, about 20 times to about 800 times, about 20 times to about 500 times, about 20 times to about 300 times, about 20 times to about 250 times, about 20 times to about 200 times, about 20 times to about 150 times, about 20 times to about 120 times, about 20 times to about 100 times, about 20 times to about 80 times, about 20 times to about 50 times, about 20 times to about 30 times, about 50 times to about 1,000 times, about 50 times to about 500 times, about 50 times to about 350 times, about 50 times to about 300 times, about 50 times to about 250 times, about 50 times to about 150 times, or about 50 times to about 100 times to form the deposited layer of aluminum oxide.

Each of the deposited layers of aluminum oxide after each ALD cycle can have a thickness of about 0.1 nm, about 0.2 nm, about 0.3 nm, about 0.4 nm, about 0.5 nm, about 0.8 nm, about 1 nm, about 2 nm, about 3 nm, about 5 nm, about 8 nm, about 10 nm, about 12 nm, or about 15 nm to about 18 nm, about 20 nm, about 25 nm, about 30 nm, about 40 nm, about 50 nm, about 60 nm, about 80 nm, about 100 nm, about 120 nm, or about 150 nm. For example, each of the deposited layers of aluminum oxide after each ALD cycle can have a thickness of about 0.1 nm to about 150 nm, about 0.2 nm to about 150 nm, about 0.2 nm to about 120 nm, about 0.2 nm to about 100 nm, about 0.2 nm to about 80 nm, about 0.2 nm to about 50 nm, about 0.2 nm to about 40 nm, about 0.2 nm to about 30 nm, about 0.2 nm to about 20 nm, about 0.2 nm to about 10 nm, about 0.2 nm to about 5 nm, about 0.2 nm to about 1 nm, about 0.2 nm to about 0.5 nm, about 0.5 nm to about 150 nm, about 0.5 nm to about 120 nm, about 0.5 nm to about 100 nm, about 0.5 nm to about 80 nm, about 0.5 nm to about 50 nm, about 0.5 nm to about 40 nm, about 0.5 nm to about 30 nm, about 0.5 nm to about 20 nm, about 0.5 nm to about 10 nm, about 0.5 nm to about 5 nm, about 0.5 nm to about 1 nm, about 2 nm to about 150 nm, about 2 nm to about 120 nm, about 2 nm to about 100 nm, about 2 nm to about 80 nm, about 2 nm to about 50 nm, about 2 nm to about 40 nm, about 2 nm to about 30 nm, about 2 nm to about 20 nm, about 2 nm to about 10 nm, about 2 nm to about 5 nm, about 2 nm to about 3 nm, about 10 nm to about 150 nm, about 10 nm to about 120 nm, about 10 nm to about 100 nm, about 10 nm to about 80 nm, about 10 nm to about 50 nm, about 10 nm to about 40 nm, about 10 nm to about 30 nm, about 10 nm to about 20 nm, or about 10 nm to about 15 nm.

In other embodiments, the vapor deposition process is a CVD process and the method includes simultaneously exposing the rotary equipment component to the aluminum precursor and the oxidizing agent to form the deposited layer of aluminum oxide. During an ALD process or a CVD process, each of the aluminum precursor and the oxidizing agent can independent include one or more carrier gases. One or more purge gases can be flowed across the rotary equipment component and/or throughout the processing chamber in between the exposures of the aluminum precursor and the oxidizing agent. In some examples, the same gas may be used as a carrier gas and a purge gas. Exemplary carrier gases and purge gases can independently be or include one or more of nitrogen (N₂), argon, helium, neon, hydrogen (H₂), or any combination thereof.

In some embodiments, the protective coating can optionally be exposed to one or more annealing processes. In some examples, the protective coating can be converted into the coalesced film or crystalline film during the annealing process. During the annealing process, the high temperature coalesces the layers within the protective coating into a single structure where the new crystalline assembly enhances the integrity and protective properties of the coalesced film or crystalline film. In other examples, the protective coating can be heated and densified during the annealing process, but still maintained as a protective coating. The annealing process can be or include a thermal anneal (e.g., rapid thermal processing (RTP) and/or furnace annealing), a plasma anneal, a light anneal (e.g., a laser anneal, an ultraviolet anneal, an infrared anneal, or a visible light anneal), or any combination thereof.

The protective coating and/or the protective coating disposed on the rotary equipment component is heated to a temperature of about 400° C., about 500° C., about 600° C., or about 700° C. to about 750° C., about 800° C., about 900° C., about 1,000° C., about 1,100° C., about 1,200° C., or greater during the annealing process. For example, the protective coating and/or the protective coating disposed on the rotary equipment component is heated to a temperature of about 400° C. to about 1,200° C., about 400° C. to about 1,100° C., about 400° C. to about 1,000° C., about 400° C. to about 900° C., about 400° C. to about 800° C., about 400° C. to about 700° C., about 400° C. to about 600° C., about 400° C. to about 500° C., about 550° C. to about 1,200° C., about 550° C. to about 1,100° C., about 550° C. to about 1,000° C., about 550° C. to about 900° C., about 550° C. to about 800° C., about 550° C. to about 700° C., about 550° C. to about 600° C., about 700° C. to about 1,200° C., about 700° C. to about 1,100° C., about 700° C. to about 1,000° C., about 700° C. to about 900° C., about 700° C. to about 800° C., about 850° C. to about 1,200° C., about 850° C. to about 1,100° C., about 850° C. to about 1,000° C., or about 850° C. to about 900° C. during the annealing process.

The protective coating can be under a vacuum at a low pressure (e.g., from about 0.1 Torr to less than 760 Torr), at ambient pressure (e.g., about 760 Torr), and/or at a high pressure (e.g., from greater than 760 Torr (1 atm) to about 3,678 Torr (about 5 atm)) during the annealing process. The protective coating can be exposed to an atmosphere containing one or more gases during the annealing process. Exemplary gases used during the annealing process can be or include nitrogen (N₂), argon, helium, hydrogen (H₂), oxygen (O₂), or any combinations thereof. The annealing process can be performed for about 0.01 seconds to about 10 minutes. In some examples, the annealing process can be a thermal anneal and lasts for about 1 minute, about 5 minutes, about 10 minutes, or about 30 minutes to about 1 hour, about 2 hours, about 5 hours, or about 24 hours. In other examples, the annealing process can be a laser anneal or a spike anneal and lasts for about 1 millisecond, about 100 millisecond, or about 1 second to about 5 seconds, about 10 seconds, or about 15 seconds.

In one or more examples, the containing aluminum oxide can be produced by delivering the precursor (e.g., trimethylaluminum at a temperature of about 0° C. to about 30° C.) to the rotary equipment component via vapor phase delivery for at pre-determined pulse length of about 0.1 seconds. During this process, the deposition reactor is operated under a flow of nitrogen carrier gas (about 100 sccm total) with the chamber held at a pre-determined temperature of about 150° C. to about 350° C. and pressure about 1 Torr to about 5 Torr. After the pulse of trimethylaluminum, the chamber is then subsequently pumped and purged of all requisite gases and byproducts for a determined amount of time. Subsequently, water vapor is pulsed into the chamber for about 0.1 seconds at chamber pressure of about 3.5 Torr. An additional chamber purge is then performed to rid the reactor of any excess reactants and reaction byproducts. This process is repeated as many times as necessary to get the target aluminum oxide film to the desired film thickness. The rotary equipment component is then subjected to an annealing furnace at a temperature of about 500° C. under inert nitrogen flow of about 500 sccm for about one hour.

Embodiments of the present disclosure further relate to any one or more of the following examples 1-26:

1. A coated turbocharger component, comprising: a metallic substrate comprising a nickel-based alloy or superalloy, a cobalt-based alloy or superalloy, a stainless steel, or a titanium-aluminum alloy; and a protective coating disposed on the metallic substrate, wherein the protective coating comprises an aluminum oxide having a purity of greater than 99 atomic percent (at %).

2. A coated turbocharger component, comprising: a metallic substrate, wherein the metallic substrate is a turbine wheel, a compressor wheel, an impeller, a fan blade, a disk, a heat shield, a pulley, or a shaft; and a protective coating disposed on the metallic substrate, wherein the protective coating comprises an aluminum oxide having a purity of greater than 99 atomic percent (at %).

3. The coated turbocharger component according to example 1 or 2, wherein the aluminum oxide has a purity of 99.9 at % or greater.

4. The coated turbocharger component according to example 1 or 2, wherein the aluminum oxide has a purity of 99.99 at % or greater.

5. The coated turbocharger component according to example 1 or 2, wherein the aluminum oxide has a purity of 99.999 at % or greater.

6. The coated turbocharger component according to example 1 or 2, wherein the aluminum oxide has a purity of 99.9999 at % or greater.

7. The coated turbocharger component according to any one of examples 1-6, wherein the aluminum oxide comprises one or more elements selected from hafnium, titanium, chromium, yttrium, zirconium, niobium, platinum, palladium, silicon, rhodium, ytterbium, strontium, barium, lanthanide, cerium, neodymium, samarium, gadolinium, terbium, dysprosium, holmium, erbium, thulium, lutetium, oxides thereof, or any combination thereof.

8. The coated turbocharger component according to any one of examples 1-7, wherein the aluminum oxide comprises less than 0.1 at % of an impurity, and wherein the impurity comprises sulfur, carbon, nitrogen, nickel, cobalt, tantalum, or any combination thereof.

9. The coated turbocharger component according to example 8, wherein the aluminum oxide comprises less than 0.01 at % of the impurity.

10. The coated turbocharger component according to example 9, wherein the aluminum oxide comprises less than 0.001 at % of the impurity.

11. The coated turbocharger component according to example 10, wherein the aluminum oxide comprises less than 0.0001 at % of the impurity.

12. The coated turbocharger component according to any one of examples 1-11, wherein the protective coating has a thickness of about 100 nm to about 2,000 nm.

13. The coated turbocharger component according to example 12, wherein the protective coating has a thickness of about 200 nm to about 1,000 nm.

14. The coated turbocharger component according to example 13, wherein the protective coating has a thickness of about 300 nm to about 700 nm.

15. The coated turbocharger component according to any one of examples 1-14, wherein the protective coating has a thickness variation of less than 20%.

16. The coated turbocharger component according to example 15, wherein the protective coating has a thickness variation of less than 10%.

17. The coated turbocharger component according to example 16, wherein the protective coating has a thickness variation of less than 5%.

18. The coated turbocharger component according to any one of examples 1-17, wherein the metallic substrate is a turbine wheel, a compressor wheel, an impeller, a fan blade, a disk, a heat shield, a pulley, or a shaft.

19. The coated turbocharger component according to any one of examples 1-18, wherein the metallic substrate comprising a nickel-based alloy or superalloy, a cobalt-based alloy or superalloy, a stainless steel, or a titanium-aluminum alloy.

20. The coated turbocharger component according to any one of examples 1-19, wherein the metallic substrate comprises a metal selected from Inconel 713 (IN713) alloy, Inconel 713C (IN713C) alloy, Inconel 713LC (IN713LC) alloy, titanium-aluminum, M247 nickel-based alloy, RCV11 nickel-base alloy, RCV09 nickel-based alloy, a Haste alloy or superalloy, an austenitic stainless steels, variants thereof, or combinations thereof.

21. The coated turbocharger component according to any one of examples 1-20, wherein the metallic substrate is completely coated with or encapsulated by the protective coating.

22. The coated turbocharger component according to any one of examples 1-21, wherein the protective coating has a surface roughness (Ra) of about 1 μm to about 100 μm.

23. The coated turbocharger component according to any one of examples 1-22, wherein the protective coating is deposited by an atomic layer deposition (ALD) process, a plasma-enhanced ALD (PE-ALD) process, a thermal chemical vapor deposition (CVD) process, a plasma-enhanced CVD (PE-CVD) process, a pulsed-CVD process, a physical vapor deposition (PVD) process, or any combination thereof.

24. A coated turbocharger component, comprising: a metallic substrate, wherein the metallic substrate is a turbine wheel or a compressor wheel; and a protective coating disposed on the metallic substrate, wherein the protective coating comprises an aluminum oxide having a purity of greater than 99.9 atomic percent (at %), wherein the aluminum oxide comprises less than 0.1 at % of an impurity, and wherein the impurity comprises sulfur, carbon, nitrogen, nickel, cobalt, tantalum, or any combination thereof.

25. A method for depositing a coating on a coated turbocharger component, comprising: positioning a metallic substrate, wherein the metallic substrate is a turbine wheel, a compressor wheel, an impeller, a fan blade, a disk, a heat shield, a pulley, or a shaft; and depositing a protective coating on the metallic substrate, wherein the protective coating comprises an aluminum oxide having a purity of greater than 99 atomic percent (at %).

26. The method according to example 25, wherein the protective coating is deposited by an atomic layer deposition (ALD) process, a plasma-enhanced ALD (PE-ALD) process, a thermal chemical vapor deposition (CVD) process, a plasma-enhanced CVD (PE-CVD) process, a pulsed-CVD process, a physical vapor deposition (PVD) process, or any combination thereof.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A coated turbocharger component, comprising:
a metallic substrate comprising a nickel-based alloy, a cobalt-based alloy, a stainless steel, or a titanium-aluminum alloy, wherein the metallic substrate is a turbine wheel, a compressor wheel, an impeller, a fan blade, a disk, a heat shield, a pulley, or a shaft; and
a protective coating disposed on the metallic substrate, wherein the protective coating comprises an aluminum oxide having a purity of greater than 99 atomic percent (at %).

2. The coated turbocharger component of claim 1, wherein the aluminum oxide has a purity of 99.9 at % or greater.

3. The coated turbocharger component of claim 1, wherein the aluminum oxide has a purity of 99.999 at % or greater.

4. The coated turbocharger component of claim 1, wherein the aluminum oxide comprises one or more elements selected from hafnium, titanium, chromium, yttrium, zirconium, niobium, platinum, palladium, silicon, rhodium, ytterbium, strontium, barium, lanthanide, cerium, neodymium, samarium, gadolinium, terbium, dysprosium, holmium, erbium, thulium, lutetium, oxides thereof, or any combination thereof.

5. The coated turbocharger component of claim 1, wherein the aluminum oxide comprises less than 0.1 at % of an impurity, and wherein the impurity comprises sulfur, carbon, nitrogen, nickel, cobalt, tantalum, or any combination thereof.

6. The coated turbocharger component of claim 5, wherein the aluminum oxide comprises less than 0.001 at % of the impurity.

7. The coated turbocharger component of claim 1, wherein the protective coating has a thickness of about 100 nm to about 2,000 nm.

8. The coated turbocharger component of claim 1, wherein the protective coating has a thickness of about 300 nm to about 700 nm.

9. The coated turbocharger component of claim 1, wherein the protective coating has a thickness variation of less than 10%.

10. The coated turbocharger component of claim 1, wherein the metallic substrate comprises a metal selected from Inconel 713 (IN713) alloy, Inconel 713C (IN713C) alloy, Inconel 713LC (IN713LC) alloy, titanium-aluminum, M247 nickel-based alloy, RCV11 nickel-base alloy, RCV09 nickel-based alloy, a Haste superalloy, an austenitic stainless steels, variants thereof, or combinations thereof.

11. The coated turbocharger component of claim 1, wherein the metallic substrate is completely coated with or encapsulated by the protective coating.

12. The coated turbocharger component of claim 1, wherein the protective coating has a surface roughness (Ra) of about 1 μm to about 100 μm.

13. The coated turbocharger component of claim 1, wherein the protective coating is deposited by an atomic layer deposition (ALD) process, a plasma-enhanced ALD (PE-ALD) process, a thermal chemical vapor deposition (CVD) process, a plasma-enhanced CVD (PE-CVD) process, a pulsed-CVD process, a physical vapor deposition (PVD) process, or any combination thereof.

14. A coated turbocharger component, comprising:
a metallic substrate, wherein the metallic substrate is a turbine wheel or a compressor wheel; and
a protective coating disposed on the metallic substrate, wherein the protective coating comprises an aluminum oxide having a purity of greater than 99.9 atomic percent (at %), wherein the aluminum oxide comprises less than 0.1 at % of an impurity, and wherein the impurity comprises sulfur, carbon, nitrogen, nickel, cobalt, tantalum, or any combination thereof.

15. The coated turbocharger component of claim 14, wherein the aluminum oxide has a purity of 99.999 at % or greater.

16. The coated turbocharger component of claim 14, wherein the aluminum oxide comprises less than 0.1 at % of an impurity, and wherein the impurity comprises sulfur, carbon, nitrogen, nickel, cobalt, tantalum, or any combination thereof.

17. The coated turbocharger component of claim 16, wherein the aluminum oxide comprises less than 0.001 at % of the impurity.

18. The coated turbocharger component of claim 14, wherein the protective coating has a thickness of about 300 nm to about 700 nm, and wherein the protective coating has a thickness variation of less than 10%.

19. The coated turbocharger component of claim 14, wherein the protective coating has a surface roughness (Ra) of about 1 μm to about 100 μm.

20. A method for depositing a coating on a coated turbocharger component, comprising:
positioning a metallic substrate, wherein the metallic substrate is a turbine wheel, a compressor wheel, an impeller, a fan blade, a disk, a heat shield, a pulley, or a shaft; and
depositing a protective coating on the metallic substrate, wherein the protective coating comprises an aluminum oxide having a purity of greater than 99 atomic percent (at %).
